(19) United States
(12) Patent Application Publication
(10) Pub. No.: US 2003/0202317 A1
(43) Pub. Date: Oct. 30, 2003

(54) Desk housing upgradable and expandable computer, network and multimedia systems

(76) Inventor: Ben Jans, Antwerpen (BE)

Correspondence Address: ROPES & GRAY LLP, ONE INTERNATIONAL PLACE, BOSTON, MA, 02110-2624, US

(21) Appl. No.: 10/105,671

(22) Filed: Mar. 25, 2002

(51) Int. Cl. H05K 5/00

(52) U.S. Cl. 361/683

(57) ABSTRACT

A desk incorporating full function computer, multimedia and networking systems that are concealed from view but are readily accessible to the user. The desk includes a digital equipment rack system which houses and interconnects a wide range of computer and multimedia components and permits facile upgrades and expansions of these components. The desk integrates the rack in a manner that attenuates noise generated by associated electronic components while facilitating the cooling of these components. The computer and multimedia systems incorporated by the desk may be accessed and controlled through a central control touch screen.

### FIELD OF THE INVENTION

This invention relates to computer and multimedia workstations or desks which integrate and conceal computer, multimedia, telecommunications and networking components while providing the user with ready access to these components for the purposes of use, interconnectivity and replacement.

### BACKGROUND OF THE INVENTION

Over the past three decades, both personal and networked computers have become an essential component of the modem office environment. During this time, the appearance and function of workstations and desks has changed dramatically in order to accommodate computers and an ever-expanding host of peripheral devices. Today, many workstations and desks incorporate keyboard trays, power cable pass through openings and a variety of other features designed to facilitate the use of a personal or networked computer. Some attempts have been made to completely enclose computer systems in the interior compartments of a desk. For example, U.S. Pat. No. 4,766,422 for “Computer Integrated Desk” discloses a desk having a computer, video display, keyboard, disk drives and printer completely concealed within the desk and quickly convertible to a fully operable computer work station by exposing the keyboard at a central location, raising the video display and accessing the computer, disk drives and printer by opening a door to the interior of the desk.

U.S. Pat. No. 4,755,009 for “Work Station Apparatus for Word Processing Equipment” discloses a desk housing a display terminal unit visible through the top surface of the desk and a central processing unit, disk drive, keyboard unit and printer unit disposed in various interior regions of the desk.

U.S. Pat. No. 5,033,804 for “Multimedia Workstation” describes an electronic office workstation enabling user access to communication, entertainment, record keeping, computation, environmental control, writing and miscellaneous functions.

U.S. Pat. No. 6,286,440 for “Computer in a Desk” discloses a school, home or commercial desk that can be used for traditional tasks while providing readily available access to computer equipment.

As will be apparent, none of the prior art computer workstations listed above solve the problems created by rapidly developing computer hardware technology and increasingly demanding computer users. This prior art does not permit existing digital components to be readily replaced with updated components or augmented with additional, interconnected devices. The prior art also fails to address how multiple, heat generating and heat sensitive digital devices can be effectively cooled in a confined space within the desk while shielding the user from noise generated by these devices. Finally, this prior art does not describe a centralized control device that facilitates the input of security access information to a central processor and can be used to direct the functions of the central processor once the security access information has been confirmed and access to the central processing unit has been granted.

### SUMMARY OF THE INVENTION

The systems and methods described herein comprise a desk that integrates multiple computer, network and multimedia systems. In one embodiment, the desk resembles a conventional desk or work station with a work surface and various storage compartments. The interior of the desk, however, houses computing, networking and multimedia electronics that are accessible to the user through a series of doors, slots and other access points incorporated into the overall design of the desk. The electronic equipment and connections are concealed from view until accessed by to the user.

The main work surface of the desk may be supported at least in part by a CCU module having sidewalls forming an interior compartment and an outer structure capable of supporting one or both ends of the work surface. In one embodiment, the interior compartment of the CCU module houses a digital equipment rack system which in turn houses, powers and electrically interconnects digital equipment such as a central processing unit, networking equipment, multimedia equipment and a plurality of peripheral digital devices. This rack system allows the user to add and remove digital equipment from the desk's electronic systems with relative ease, facilitating upgrades and system expansion. The rack system may be partially surrounded by a sound protective material that attenuates noise generated by the digital devices housed within the digital equipment rack. In addition, the sound protective material may form an airflow pocket around the digital equipment rack. One or more electric fans within this airflow pocket may be used to draw air into the airflow pocket through one or many air intake openings disposed within a bottom sidewall of the interior compartment, pass the air over the digital equipment housed by the digital equipment rack, and expel the air through one or many air exhaust openings disposed within a top sidewall of the interior compartment. In alternate embodiments, the airflow pocket may be formed by elements other than the sound protective material, including the sidewalls of the interior compartment.

The desk may also incorporate various digital devices located outside of the CCU module that are electrically connected to the digital equipment rack and/or the devices it houses. An output module may be attached to the back of the desk to house various output devices including LCD computer and television displays as well as certain input devices including LAN antennas and a digital video camera. The devices contained in the output module may be mounted to electric lifts that raise the devices above the work surface when they are required for use and lower the devices to a stored position below the work surface when they are not in use. Optionally, a central control touch screen may be mounted to the exterior of the CCU module while being electrically connected to a central processing unit and other devices housed in the digital equipment rack. This central control touch screen allows the user to input security information into the central processing unit in order to verify use authorization. Once use authorization is granted, the central control touch screen may function as an input/output device from which the user may control the functions of the central processing unit and other digital and electronic devices incorporated into the desk. Additional digital devices may be linked to the digital equipment rack and the devices it houses through a variety of plug-sockets and wireless inputs located within the work surface, the output module and an optional organization module that is designed primarily for storage. In one embodiment of the desk, varying types of plug-sockets, controls and power outlets may be grouped in one location and accessed through a universal connector panel.

Overall, the desk provides the user with a large, usable workspace that is computer and peripheral free. This workspace, however, can be rapidly transformed using the central control touch screen into a state of the art, full function computing, networking and multimedia center. The computing, networking and multimedia capabilities of the desk are readily expandable and upgradeable, ensuring that the invention will not become obsolete as technology advances.

### BRIEF DESCRIPTION OF THE DRAWINGS

The foregoing and other objects and advantages of the invention will be appreciated more fully from the following further description thereof, with reference to the accompanying drawings wherein;

FIG. 1 depicts a front perspective view of the desk with output devices at the back of the work surface extended to a visible position above the work surface;

FIG. 2 depicts a front perspective view of the desk with output devices at the back of the work surface retracted to a hide position below the work surface;

FIG. 3 depicts a front perspective view of the top of the work surface;

FIG. 4 depicts a front perspective view of the underside of the work surface;

FIG. 5 depicts a front perspective view of the CCU module;

FIG. 6 depicts a side view of the CCU module with the side panel removed;

FIG. 7 depicts a top perspective view of the CCU module configured with empty shelves for digital devices and controls;

FIG. 8 depicts a front perspective view of the central control touch screen;

FIG. 9 depicts a front perspective view of the central control touch screen attached to the desk light assembly;

FIG. 10 depicts a front perspective view of the organization module; and

FIG. 11 depicts a front perspective view of the universal connector panel.

### DETAILED DESCRIPTION OF THE INVENTION

To provide an overall understanding of the invention, certain illustrative embodiments will now be described. However, it will be understood by one of ordinary skill in the art that the desk described herein can be readily adapted and modified to a plurality of configurations and that such other additions and modifications will not depart from the scope hereof.

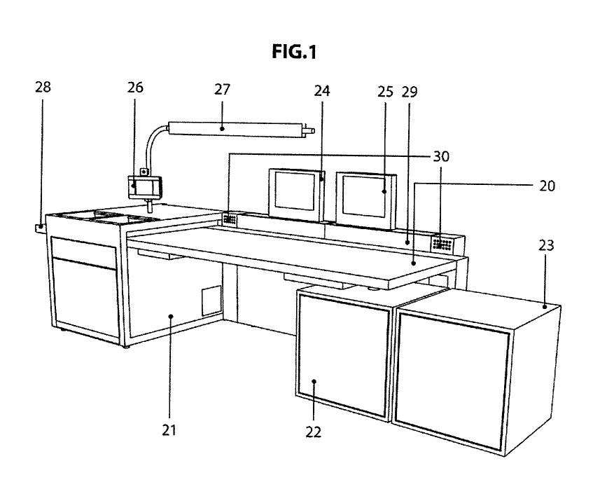

In general, as shown in FIG. 1, one embodiment of the apparatus and system described herein comprises a desk having a work surface 20 supported at one end by a CCU module 21 and an organization module 22 at the other end. Although illustrated as a dual pedestal, free-standing desk supported by a CCU module 21 and an organization module 22, it should be understood that the desk may be readily adapted to a desk supported by a CCU module 21 at both ends, a desk supported by a CCU module 21 at one end and a rigid structure such as a wall at the other end, a desk supported by a CCU module 22 serving as a single pedestal for supporting the work surface 20, or adapted to be hung from a wall. The exterior of the desk may be finished with a variety of natural or manmade water-resistant materials ranging from wood and granite to plastic and metal.

An output module 23 may be attached to the rear of the desk. One of ordinary skill in the art will recognize that a separate output module 23 is not necessary to enable the functionality of the desk and that each component and function of the output module depicted may be incorporated into other portions of the desk including the work surface 20, the CCU module 21 and the organization module 22. The output module 23 may be double-walled, enabling it to conceal the devices and electrical connections that it contains from view. In one embodiment, a wireless receiver/transmitter 29 may be embedded into the front face of output module 23, above the work surface 20. This wireless receiver/transmitter may be electrically connected to the central processing unit 81 of the CCU module 21, and may enable the central processing unit to establish wireless connections with remote controls, cellular phones, portable computers, palm held devices and a variety of other hand held devices. One of ordinary skill in the art will recognize that this wireless receiver/transmitter may be positioned at various other locations on and within the desk, including the work surface 20, CCU module 21, touch screen 26 and organization module 22 and may consist of various types of receiver/transmitters, including an infrared receiver/transmitter. Audio speakers 30 may be embedded into the double walled housing of the output module or various other locations on and within the desk.

The output module 23 may house one or many electric power lifts attached to one or many input and/or output devices. Each electric power lift may be arranged such that it is capable of moving one or many input and/or output devices between a stored position within the output module 23 to a visible position above the work surface 20 that is accessible from the work surface 20. Each electric power lift may be capable of independent operation permitting none, one, or many input and/or output devices to be displayed at any given time. One embodiment of this desk includes two output devices, a flat-screen LCD computer display 24 and a flat-screen LCD television display 25, each mounted to an electric power lift. Alternate embodiments of the desk may include any of a variety of types and sizes of display devices that may be located at different positions on or about the work surface 20. Multiple input and/or output devices may be attached to a single electric power lift. One of ordinary skill in the art will recognize that various input devices such as digital video cameras and various types of receiver/transmitters, including wireless LAN, RF, infrared and Bluetooth receiver/transmitters, may also be attached to electric power lifts in the output module 23.

The depicted desk incorporates a central control touch screen 26 that is positioned to be accessible to a user seated in front of the desk. The central control touch screen 26 may be embedded into or mounted to the top of the CCU module 21, embedded into or mounted on the top of the work surface 20, or otherwise attached to the exterior of the desk. One embodiment of the desk includes a desk light 27 attached to and protruding from the CCU module 21, to which the central control touch screen 26 is attached. In an alternate embodiment, the central control touch screen 26 is mounted to an electroscopic or manual pneumatic lift protruding from the exterior of the desk.

The desk may also incorporate a secondary work surface 28 attached to the side of the CCU module 21 opposite the work surface 20. It will be apparent to one of ordinary skill in the art that the desk may incorporate one or many secondary work surfaces attached to various exposed surfaces of the desk.

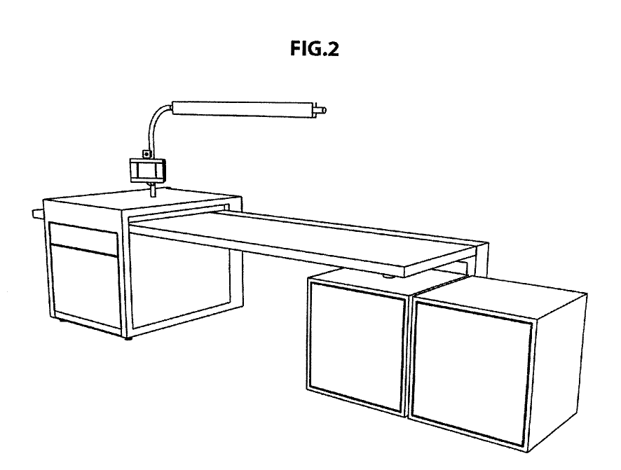

One of the primary advantages of the described desk is that it is capable of concealing computing and peripheral devices from view when they are not in use. FIG. 2 depicts the desk with all output devices, with the exception of the central control touch screen 26, concealed from view.

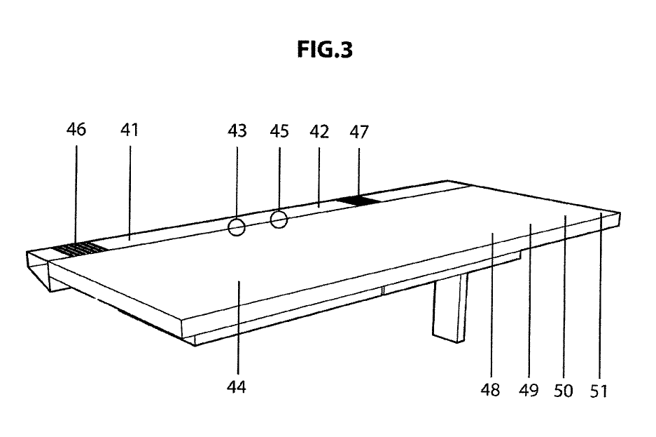

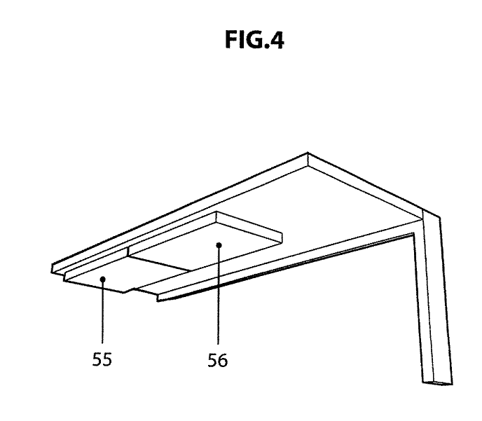

FIGS. 3 and 4 depict a top and an underside view, respectively, of the work surface 20. The work surface 20 may incorporate one or many recessed cavities 41, 42 housing power outlets for charging external digital devices, a variety of ports that allow external digital devices to be electrically connected to the central processor or other digital devices incorporated in the desk, and controls for audio, video, communications and I/O devices incorporated into the desk. The work surface may also incorporate one or many recessed cavities 41, 42 housing computer plug-socket connections, telephony connections, and network connections or these connections may be consolidated into one or many universal connector panels incorporated into the recessed cavities. Slides or covers that are flush with and blend into the work surface 20 may conceal these recessed cavities. The user, exposing the outlets, ports or other electrical connection points below, may manually retract these slides. One embodiment of the desk includes two such recessed cavities. The first recessed cavity 41 houses USB and Fire Wire plug-sockets, as well as RJ plug-sockets for LAN or telephony connections. A second recessed cavity 42 houses power outlets. Additionally, the work surface may integrate an omni-directional microphone 43, a headphone plug-socket 44, and an infrared receiver 45, a graphics digitizer tablet 48, an e-signature pad 49, a touch pad pointing device 50 and a fingerprint identification unit 51.

Pull drawers or moveable shelves may be mounted to the underside of the work surface. In one embodiment of the desk, a first pull drawer 55 so mounted houses a wireless/infared keyboard and mouse. A user may open this drawer and move said wireless/infrared keyboard and mouse to the top of the work surface when their use is required. A second pull drawer 56 located on the underside of the work surface may be used to store an ultra-flat scanner or a variety of other thin, digital devices.

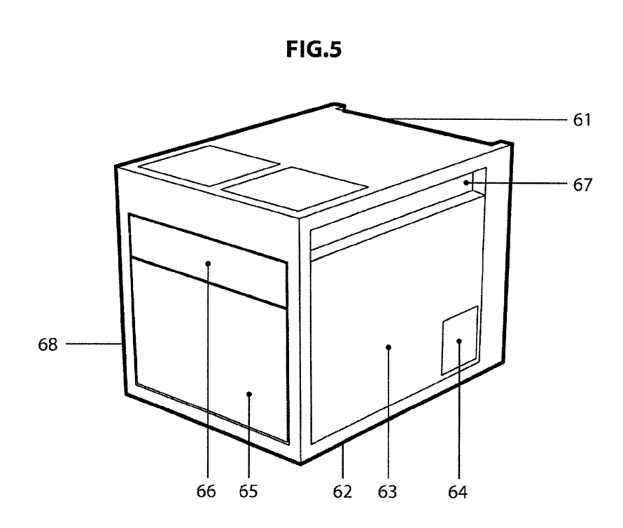

FIG. 5 depicts a perspective view of the exterior of the CCU module. The CCU module may house one or many central processing units and a variety of peripheral, digital devices as well as network and multimedia components. These electrical devices and components may be arranged to be easily accessible, easily interconnected with digital devices inside and outside the CCU module, and well ventilated. A removable frontal servicing panel 65 and removable lateral servicing panels 63, 68 may be incorporated into the design to permit the user to access the interior of the CCU module. A computer interface access 66 may be incorporated for the same purpose. One embodiment of the desk includes a subwoofer sound channel 64 that provides a channel through which audible subwoofer output may pass while the lateral servicing panel 63 is in place. A cable pass through 67 may provide a channel through which cables may extend from electronic devices outside the CCU module to digital devices, power supplies and port plug-sockets contained within the CCU module. Finally air intake openings 62 disposed within the bottom sidewall of the CCU module and an air exhaust opening 61 disposed within the top sidewall of the CCU module may be incorporated into the design to permit air to flow into and out of the interior of the CCU module.

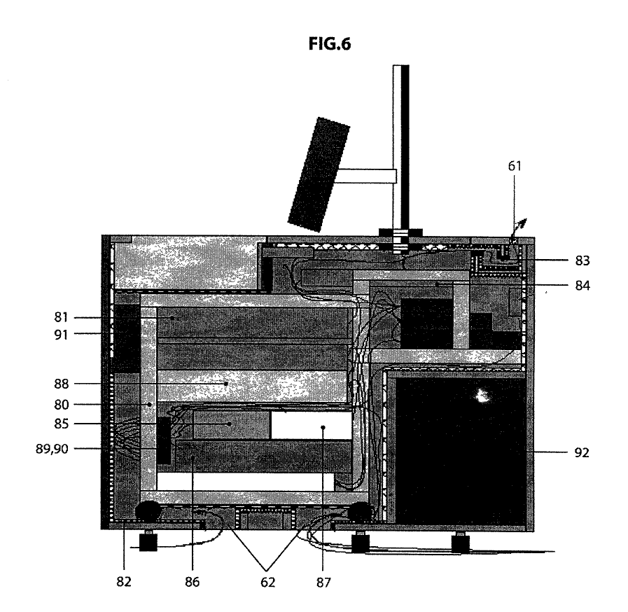

FIG. 6 depicts the interior compartment of the CCU module. The CCU module may house a digital equipment rack 80 capable of mechanically attaching one or many central processing units 81, one or many peripheral devices, networking components, servers 88, multimedia components and telecommunications components to the interior of the CCU module and facilitating the electrical interconnection of these components and devices with each other and with other devices and components located outside of the CCU module. The digital equipment rack 80 may also incorporate a power supply with multiple power plug-sockets which supply power to the components and devices housed by the rack. The digital equipment rack 80 may be designed such that individual components and devices may be installed and removed as individual units, leaving the other components and devices in the rack and associated wire connections in tact. Further, removal and installation of such devices may be accomplished by removing the frontal servicing panel 65 and/or the lateral servicing panels 63, 68 without the need to further disassemble the CCU module. A sound protective material 82 such as fiberglass, vibration absorbent polyester, sound board, cotton batting, light resilient polystyrene plastic, recycled paper fiberboard or dried sea grass may partially surround the digital equipment rack 80 and one or many electric fans 84, leaving a sufficient airflow pocket 83 around the rack through which air may pass. In one embodiment of the desk, an electric fan 84 is positioned within the airflow pocket 83 such that when it is in operation, it draws ambient air into the interior of the CCU module through the air intake openings 62, passes the ambient air over the central processing unit 81 and other digital and electrical components housed in the digital equipment rack 80, and expels the air through the air exhaust opening 61. This flow of ambient air serves to cool the electronic devices housed by digital equipment rack 80 with the goal of maintaining an ambient temperature of between 20° C. and 30° C. within the CCU module. In alternate embodiments of the desk, the number of fans positioned within the airflow pocket 83 may be increased or decreased in order to increase or decrease the range of ambient temperatures that may be maintained within the CCU module. The fans incorporated into the desk may be temperature controlled and programmed to run at higher RPMs (displacing a greater volume of air through the airflow pocket 83) as the ambient temperature in the CCU module increases. Conversely, these temperature controlled fans would run at lower RPMs and generate less audible noise as the ambient temperature in the CCU module decreased. A combination of single-speed and temperature controlled fans may be used to ensure redundancy while reducing the amount of audible noise produced by the fans. The sound protective material 82 which forms the outer boundary of the airflow pocket 83 may also attenuate the sound generated by the central processing unit 81, electric fans 84 and other digital devices enclosed within, reducing the noise from these devices that is audible to the desk's user. In one embodiment of the desk, the interior of the CCU module incorporates built-in sensors that monitor the airflow, temperature and noise within the CCU module so that they may be monitored and controlled by the central processor 81.

One embodiment of the desk incorporates a standard 19-inch EIA-standard digital equipment rack system capable of housing the following components commercially available as standard 19-inch EIA-standard digital equipment rack compatible units: a central processing unit (with motherboard, random access memory, read only memory, I/O cards, processor, video card, LAN cards, modem/fax card and TV/radio card) 81, one or more hard drives, a network router or switch 85, a modem unit (a cable and/or an ASDL modem) 87, an Internet firewall device 86, a backup device, a central server PC (capable of functioning as a data server or a print server) 88, and an input/output device module 91 that contains a plurality of input/output devices including a floppy drive, a CD-ROM drive, a DVD recordable drive (capable of writing and reading DVD-RW, DVD-R, DVD-ROM, CD-R, CD-RW and CD-ROM media), and a magnetic/chip card reader. (The input/output device module of this embodiment may be positioned within the CCU module such that the floppy drive, CD-ROM player, DVD recordable drive, magnetic/chip card reader and backup drive are accessible to the user using a slot in the computer interface access 66. Alternatively, these devices may be housed in a separate compartment within the CCU module 21, organization module 22 or the work surface 20.) A UTP patch panel 89 may interconnect the network devices in this embodiment while the multimedia and communications devices in this embodiment may be interconnected by a RF patch panel 90, both panels being attached to the wall of the digital equipment rack 80. The devices may be powered by a primary and a secondary (redundant) power supply integrated into the digital equipment rack 80. A subwoofer 91 and/or other speakers may be positioned behind the digital equipment rack 80, outside of the sound protective barrier 82 and aligned with the subwoofer sound channel 64. Audio output signals processed by the central processing unit 81 or any other device in the desk may be electrically connected to a central A/V switch, which selectively directs the audio output signals to the subwoofer 91 enclosed in the CCU module 21, the speakers 30 embedded in the output module 23 and any other audio output devices incorporated into the desk.

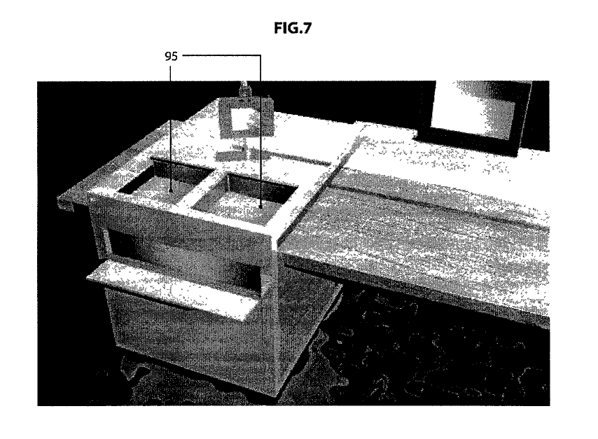

As depicted in FIG. 7, the CCU module may contain shelves 95 with appropriate plug-sockets and a variety of ports for digital devices to accommodate external peripherals such as USB, Fire Wire, parallel, serial and IDE/SCSI devices and RJ plug-sockets for LAN or telephony/fax connections. Further, these shelves 95 may be configured to house controls for audio, video and I/O devices. A universal connector panel with power sockets may also be installed into the shelves 95 of the CCU module to facilitate the interconnection of digital devices located outside of the digital equipment rack 80.

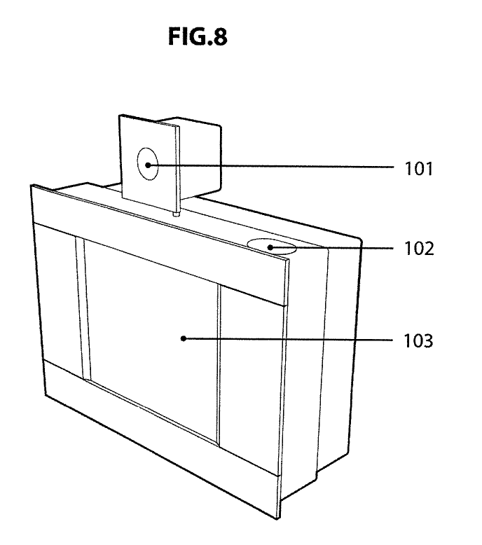

FIG. 8 depicts a central control touch screen 26 which may be electrically connected to the central processing unit 81 housed in the CCU module 21 and mounted to the desk in a location that is accessible to a user seated in front of the desk. The central control touch screen 26 may be activated once sensors incorporated into the desk indicate that a user has moved into a position in front of the desk. One skilled in the art will recognize that these sensors may include a variety of devices including optical, thermal, audio and pressure detectors. Once activated, the central control touch screen 26 may enable the user to input access information such as a fingerprint, an alphanumeric character sequence or a digital pen stroke in order to obtain digital access to the central processing unit 81. These inputs may be made using a fingerprint touchpad 102 and/or a touch sensitive input screen 103 incorporated into the central control touch screen 26.

This touch sensitive input screen 103 may include additional features such as a virtual keyboard or icons to assist the user. In one embodiment of the desk, the touch sensitive input screen 103 is connected to the controller described in U.S. Pat. No. 5,956,020 for “Touch screen Controller with Pen and/or Finger Inputs,” enabling the user to input information through the touch screen using a touch pen or his finger. In another embodiment, a data encrypted touch screen such as that described in U.S. Pat. No. 5,970,146 for “Data Encrypted Touchscreen” may be used to permit the user to communicate with the central processing unit 81 in both a normal and encrypted mode. The fingerprint touchpad may be directly integrated into touch screen in a manner similar to that described in U.S. Pat. No. 6,337,918 for “Computer System with Integratable Touchpad/Security Subsystem” or may be separately connected to the central processing unit 81 in a manner similar to that described in U.S. Pat. No. 6,256,402 for “Password Input Apparatus Based on Fingerprint Recognition of a Registered User of a System.” Further, one skilled in the art will recognize that there are multiple configurations of touch screens and fingerprint touch pads that can be implemented to provide the security and control functionality described herein. These configurations include touch screens and fingerprint touch pads that may operate remotely via RF link to the central processing unit 81. The central control touch screen 26 may also incorporate a startup button that, when pushed, causes the computer, network and/or the multimedia systems integrated into the desk to activate.

Once the user is recognized by the central processing unit as an authorized user, the central control touch screen 26 may convert into a central command center or control device through which the user can manage the functions of the central processing unit 81 and peripheral devices incorporated into the desk including, but not limited to, system startup, shutdown, reboot and backup. One skilled in the art will recognize that besides controlling these basic functions, the central control touch screen 26 can be implemented to control all or many of the computing and electrical functions of the desk and other devices connected either directly or remotely to the desk. In one embodiment of the desk, the central control touch screen 26 may be used to dim the desk light 27. The central control touch screen 26 may also function as a digital display.

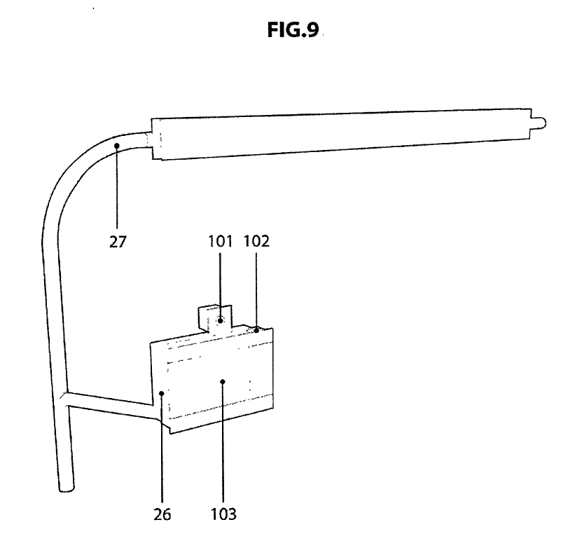

The desk may include a digital video camera and microphone assembly 101 which are mechanically attached to the top of the central control touch screen 26 and electrically connected to the central processing unit 81 and/or other digital devices housed in the digital equipment rack 80. FIG. 9 depicts how the central control touch screen 26 with attached digital video camera and microphone assembly 101 may be physically connected to the desk light 27. In an alternate embodiment, the central control touch screen 26 is mounted to an electroscopic or manual pneumatic lift protruding from the exterior of the desk.

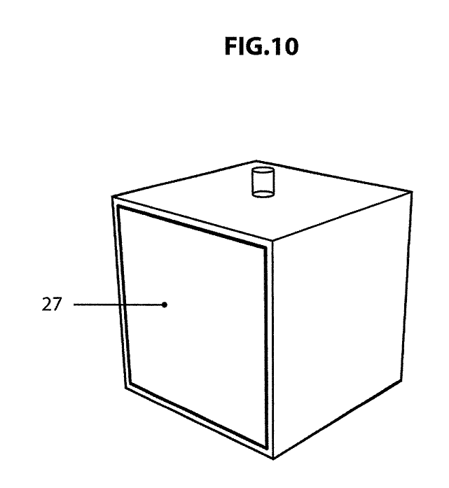

FIG. 10 depicts a front perspective view of the organization module 22. By opening the front access door 120, which may be hingedly connected to the sidewalls of the organization module 22, one may access the interior of the organization module 22. The interior of the organization module may be arranged in multiple configurations to house common office materials and equipment ranging from paper and staplers to a scanner, fax and printer. The depicted desk includes electrical outlets and plug sockets for RJ plug-sockets for Lan or Fax connections, USB, Fire Wire, parallel, serial and IDE/SCSI devices that are physically mounted inside the organization module and electrically connected to the central processing unit 81 and primary power supply contained in the digital equipment rack 80 of the CCU module 21. The organization module 22 may also house a universal connector panel.

Electrical devices located outside of the CCU module 21 may be electrically connected to the digital equipment rack 80 and/or the components and devices housed within the digital equipment rack 80 by various power and data carrying wires in addition to wireless data connections. These wires may be channeled from their respective devices through a series of recesses in the work surface 20 and output module 23 to the cable pass through 67 where they pass into the CCU module and connect through the digital equipment rack 80 to the various components and devices it houses. In one embodiment of the desk, no wires are visible from the exterior of the desk.

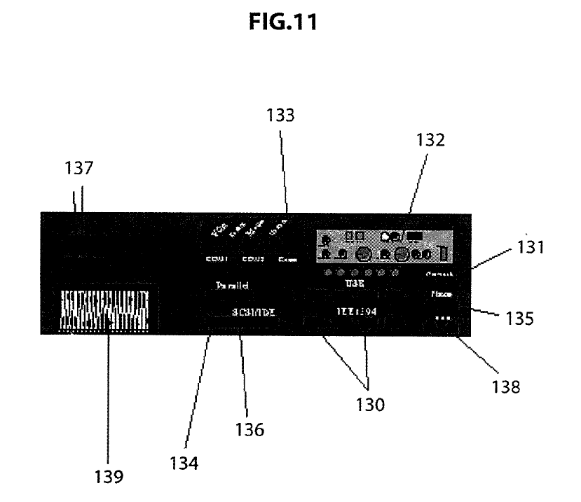

FIG. 11 depicts a universal connector panel that can be mounted in an readily accessible location in the CCU module 21, work surface 20, output module 23 or organization module 22 and electrically connected to the central processing unit 81, digital equipment rack 80 or any of the digital or electrical devices incorporated into the desk. This universal connector panel may be configured to provide the user with direct, frontal access to multiple signals and power connectors. In the depicted embodiment, the universal connector panel incorporates serial communication ports (wired and wireless) 130, networking interface connectors 131, audio interface connectors 132, video interface connectors 133, bus interface connectors 134, telephony/fax interface connectors 135, parallel communications ports 136, power supplies 137, custom non-standard connections 138 and a cable feed-through 139.

Those skilled in the art will know or be able to ascertain, using no more than routine experimentation, many equivalents to the embodiments described herein. For example, the desk might be arranged to incorporate multiple digital equipment racks complying with varying electrical and design standards. This would permit devices complying with various digital rack standards to be integrated and interconnected within the overall desk design. It will also be understood that the systems described herein provides advantages over the prior art including the ability to add and replace digital devices without the need to modify the structure of the desk, an effective structure for cooling various digital devices while concealing them from view and attenuating the noise generated by the devices that is audible to the user, and providing the user with a readily accessible touch screen for securely accessing and controlling the main computing, networking and electrical functions of the desk.

Accordingly, it will be understood that the invention is not to be limited to the embodiments disclosed herein, but is to be understood from the following claims, which are to be interpreted as broadly as allowed under the law.

What is claimed is:

1. A desk having a work surface, comprising:
i) a CCU module having sidewalls forming an interior compartment and an outer structure supporting one or both ends of the work surface;
ii) a digital equipment rack formed into the interior compartment for housing, powering and/or interconnecting digital equipment such as a central processor and a plurality of peripheral devices, said digital equipment rack being the type that enables removably and replaceably installing digital equipment components;
iii) a sound protective material surrounding the digital equipment rack to attenuate noise generated by the digital equipment housed in the digital equipment rack; and
iv) at least one air intake opening disposed within a bottom sidewall of the interior compartment, an airflow pocket where the digital equipment rack is spaced away from the sidewalls of the interior compartment, at least one air exhaust opening disposed within a top sidewall of the interior compartment and one or more electric fans for flowing air through the CCU module.

2. The desk of claim 1, further comprising a central control touch screen mounted to the desk in a location accessible to a user seated in front of the desk that activates once sensors incorporated into the desk indicate that a user has positioned himself in front of the desk, said central control touch screen being electrically connected to a central processor and enabling the user to input access information to the central processor and serve as a central command center for electrical and computer components incorporated the desk and electrically connected to the central processor once access to the central processor has been granted.

3. The desk of claim 2, wherein the central control touch screen includes a fingerprint analyzer.

4. The desk of claim 2, wherein the central control touch screen includes a virtual keyboard enabling the user to input an alphanumeric character sequence.

5. The desk of claim 2, wherein the central control touch screen includes a digital pen input.

6. The desk of claim 2, wherein the central control touch screen controls the intensity of visible light radiated from a desk light attached to the desk.

7. The desk of claim 1, further comprising an electric power lift capable of moving an input or output device between a stored position and a visible position at the back of the work surface and accessible from the work surface.

8. The desk of claim 7, further comprising a plurality of electric power lifts for moving a plurality of input and/or output devices.

9. The desk of claim 8, wherein at least one of the input and/or output devices is a LCD display or LCD television.

10. The desk of claim 8, wherein at least one of the input and/or output devices is selected from the group consisting of a Bluetooth receiver/transmitter, a LAN receiver/transmitter, an infrared receiver/transmitter and a digital video camera.

11. The desk of claim 1, wherein the CCU module contains an additional compartment housing one or more digital read/write devices selected from the group of a floppy drive, a CD-ROM player, a backup device, a DVD recordable drive and a magnetic/chip card reader.

12. The desk of claim 1, wherein a server is housed in the digital equipment rack of the CCU module.

13. The desk of claim 1, wherein the digital equipment rack of the CCU module houses and integrates one or more network devices selected from the group consisting of a router, a switch, a modem, a hub, a firewall, a UTP patch panel, and an RF patch panel.

14. The desk of claim 1, wherein the desk integrates a receiver capable of receiving signals from hand-held and/or cellular communications, computing and remote control devices.

15. The desk of claim 14, wherein the receiver is an infrared receiver.

16. The desk of claim 1, wherein audio speakers are embedded into the desk.

17. The desk of claim 16, wherein the desk integrates a central audio/visual switch to route different audio sources to the speaker system.

18. The desk of claim 1, wherein the work surface contains a recessed cavity housing power outlets for charging external digital devices.

19. The desk of claim 1, wherein the work surface contains a recessed cavity housing telephony and network connections.

20. The desk of claim 1, wherein the work surface contains a recessed cavity housing plug-sockets for connecting digital devices to a central processor or other digital devices.

21. The desk of claim 1, wherein the work surface contains a recessed cavity housing controls for digital devices selected from the group consisting of audio output devices, video output devices and communications devices.

22. The desk of claim 1, wherein an omni-directional microphone is integrated into the work surface.

23. The desk of claim 1, wherein the CCU module contains one or many shelves incorporating power outlets for charging external digital devices.

24. The desk of claim 1, wherein the CCU module contains one or many shelves incorporating telephony and/or network connections.

25. The desk of claim 1, wherein the CCU module contains one or many shelves incorporating plug-sockets for connecting digital devices to a central processor or other digital devices.

26. The desk of claim 1, wherein the CCU module contains one or many shelves housing controls for digital devices selected from the group consisting of audio input/output devices, video input/output devices and communications devices.

27. The desk of claim 1, wherein the CCU module contains one or many shelves incorporating one or many universal connector panels with power sockets.

28. The desk of claim 1, further comprising an organization module, the interior of said organization module being arranged to house office materials and equipment.

29. The desk of claim 28, wherein the interior of the organization module incorporates power outlets for charging digital devices.

30. The desk of claim 28, wherein the interior of the organization module incorporates telephony and/or network connections.

31. The desk of claim 1, wherein the interior of the organization module incorporates plug-sockets for connecting digital devices to a central processor or other digital devices.

32. The desk of claim 28, wherein the interior of the organization module houses controls for digital devices selected from the group consisting of audio input/output devices, video input/output devices and communications devices.

33. The desk of claim 28, wherein the interior of the organization module incorporates one or many universal connector panels with power sockets.
